(19) United States
(12) Patent Application Publication
(10) Pub. No.: US 2025/0341773 A1
(43) Pub. Date: Nov. 6, 2025

(54) RETICLE POD

(71) Applicant: ENTEGRIS, INC., Billerica, MA (US)

(72) Inventors: Huaping Wang, Eden Prairie, MN (US); Philip Stuart Glynn, Colorado Springs, CO (US); Russ V. Raschke, Chanhassen, MN (US); Brian Wiseman, Glencoe, MN (US); Anthony Mathius Tieben, Belle Plaine, MN (US)

(21) Appl. No.: 19/200,397

(22) Filed: May 6, 2025

Related U.S. Application Data
(60) Provisional application No. 63/643,077, filed on May 6, 2024.
(60) Provisional application No. 63/750,763, filed on Jan. 28, 2025.
(60) Provisional application No. 63/755,929, filed on Feb. 7, 2025.
(60) Provisional application No. 63/766,755, filed on Mar. 4, 2025.

(51) Int. Cl. G03F 1/66; G03F 7/00

(52) U.S. Cl. CPC G03F 1/66; G03F 7/70741

(57) ABSTRACT

Described are reticle pods used to support and transport a reticle in an extreme ultraviolet (EUV) lithography process.

### CROSS-REFERENCE TO RELATED APPLICATIONS

This application claims the benefit under 35 U.S.C. 119 of U.S. Provisional Patent Application No. 63/766,755 filed Mar. 4, 2025, U.S. Provisional Patent Application No. 63/755,929 filed Feb. 7, 2025, U.S. Provisional Patent Application No. 63/750,763 filed Jan. 28, 2025, and U.S. Provisional Patent Application No. 63/643,077 filed May 6, 2024, the disclosures of which are hereby incorporated herein by reference in their entirety.

### FIELD

The present description relates to reticle pods used to support and transport a reticle in an extreme ultraviolet (EUV) lithography process.

### BACKGROUND

One of the many process steps used in fabricating microelectronic and semiconductor devices is photolithography. Broadly, photolithography involves selectively exposing a specially prepared substrate surface to a source of radiation using a patterned template to create a patterned surface layer on the substrate. The patterned template, referred to as a “mask” or “reticle,” is a very flat, transparent or reflective plate that includes a pattern that is reproduced on the substrate surface by radiation that is passed through or reflected off the patterned template.

Photolithographic techniques use various wavelengths of radiation, including light in an ultraviolet range, light in a deep ultraviolet range, and light in an extreme ultraviolet range, referred to as extreme ultraviolet lithography (also known as EUV or EUVL). Extreme ultraviolet lithography is performed in an evacuated atmosphere (a low pressure environment or a “vacuum” environment) to minimize energy loss of EUV light from atmospheric gases. The reticle must therefore be moved from a cleanroom environment having an ambient (atmospheric) pressure condition, into the evacuated environment of a photolithography tool. Specialized devices referred to as “reticle pods” are used to handle the reticle in a cleanroom environment and to transfer the reticle between the cleanroom environment and the evacuated environment of the photolithography tool.

Certain reticle pod products have a “dual-pod” design that includes an inner reticle pod (a.k.a., “inner carrier” or “inner pod”) that holds and protects a reticle, and an outer reticle pod (a.k.a., “outer shell” or “outer pod”) that contains and transports the inner reticle pod. The inner reticle pod can be removed from the outer pod to transfer the reticle between a cleanroom and an evacuated interior of a photolithography tool. The inner reticle pod includes a flat lower piece referred to as a base that provides support for the reticle, and a cover that can be placed over the base and the reticle to define an interior that contains and protects the reticle. Example dual-pod designs are shown in United States Patent Publication 2021/0057248.

### SUMMARY

Reticles used in EUV photolithography include a plate made of glass or quartz with a patterned reflective surface on one side of the plate. Standard dimensions are 6 inches by 6 inches, by ¼ inch thick. However, the industry is considering reticles having larger length and width dimensions that can improve manufacturing efficiency.

Because a reticle has a small thickness, e.g., is approximately one-quarter inch thick, the reticle can experience bending, stress, and even permanent deformation when the reticle is suspended horizontally. A base of an inner reticle pod has multiple support surfaces (“reticle supports”) that contact the bottom surface of the reticle and support the reticle at corner locations. The spaced positioning of the reticle supports at corners of the base produces a span between the reticle supports that allows the reticle to bend along the length of the span, e.g., “sag” or “bow” due to gravity. Also, the inner reticle pod cover includes reticle contact surfaces that contact edges or upper surface locations of the reticle from above, which can also stress or deform the reticle.

According to the present description, a reticle can be supported by reticle supports that contact the reticle at locations to control, reduce, or minimize the amount of stress or deformation experienced by the reticle while being supported by the reticle supports. According to example arrangements for supporting a reticle, one or more reticle supports can contact and support a reticle at a side position of the reticle.

A reticle includes a first reticle side, a second reticle side, a first reticle end extending between the first reticle side and the second reticle side, and a second reticle end extending between the first reticle side and the second reticle side. A “side position” of a reticle is a location on a reticle that is a relatively shorter distance from a reticle side (measured perpendicularly from a reticle side that is closest to the position) compared to a relatively greater distance from a reticle end (measured perpendicularly from a reticle end that is closest to the position). To support a reticle at a side position of the reticle, a reticle support of a base can be located at a side position of the base.

Also as described, a reticle can be contacted by reticle contact surfaces of a cover at locations on the reticle to control, reduce, or minimize the amount of stress or deformation experienced by the reticle due to the contact with the reticle contact surfaces. According to example arrangements of reticle contact surfaces of a cover, one or more reticle contact surfaces can contact a reticle at a side position of the reticle. To contact a reticle at a side position of the reticle, a reticle contact surface of a cover can be located at a side position of the cover.

As described herein, an inner reticle pod can include reticle supports of a base, reticle contact surfaces of a cover, or a combination of these, that are adapted to contact a reticle at locations of the reticle to reduce or equalize stress on a reticle held within the inner reticle pod. Example inner reticle pods include a reduced or minimum total number of contact points between the reticle and surfaces of the inner reticle pod (reticle supports and reticle retainers). Example inner reticle pods include a base that includes one or more reticle supports located relatively closer to a side of the base and relatively farther from an end of the base, i.e., at a “side position” that is nearer to a base side than to a base end. Example inner reticle pods include a cover that includes one or more reticle contact surfaces located relatively closer to a side of the cover and relatively farther from an end of the cover, i.e., at a “side position” that is nearer to a cover side than to a cover end.

In one aspect, the description relates to an inner reticle pod adapted to contain a reticle. The inner reticle pod includes a base and a cover. The base includes: an upper base surface, a first base side, a second base side, a first base end extending between the first base side and the second base side, and a second base end extending between the first base side and the second base side, at least three reticle supports on the upper base surface, at least one of the at least three reticle supports being positioned at a side position of the base that is nearer to a base side than to a base end. The cover is adapted to engage the base and contain a reticle supported by the reticle supports.

In another aspect the description relates to a method of containing a reticle in an inner reticle pod that includes a base and a cover. The method includes: on a base that includes an upper base surface, a first base side, a second base side, a first base end extending between the first base side and the second base side, and a second base end extending between the first base side and the second base side, and at least three reticle supports on the upper base surface, placing a reticle on the base with the reticle supported by the at least three reticle supports. At least one of the at least three reticle supports is positioned at a side position of the reticle that is nearer to a reticle side than to a reticle end. The method further includes placing a cover over the base to contain the reticle supported by the reticle supports.

### BRIEF DESCRIPTION OF THE DRAWINGS

FIGS. 1A and 1B show an example base of an inner reticle pod and reticle as described.

FIGS. 2 shows an example of an inner reticle pod assembly as described.

FIGS. 3A, 3B, 4A, 4B, and 5 show examples of inner reticle pod assemblies as described.

FIG. 6 shows an example of a dual contamination pod that includes an inner reticle pod as described.

All figures are schematic and not necessarily to scale.

### DETAILED DESCRIPTION

According to the present description, an inner reticle pod includes a base and a cover that can be assembled with the cover being positioned over the base to define an inner reticle pod interior that is adapted to contain a reticle. The base includes multiple reticle supports at an upper surface of the base that provide support for the reticle, to position the reticle above an upper surface of the base. The cover includes reticle contact surfaces that contact edges or an upper surface of a reticle to limit movement of the reticle within the inner reticle pod interior while the cover is placed over the base with a reticle supported by the base.

A reticle supported by reticle supports of a base will sag or bend slightly due to gravity along a length or width of the reticle, between locations of the reticle supports. Additionally, reticle contact surfaces of a cover that contact the reticle can apply downward or lateral pressure on the reticle, which may also cause stress or deformation of the reticle. Even a very small amount of stress or deformation (bending, bowing) of a reticle is undesirable and is preferably avoided or minimized. Small amounts of bending, bowing, or creep, which may lead to permanent deformation of a reticle, can affect performance of the reticle and reduce the yield of a photolithography process that uses the reticle. Such deformation, bending, etc., and yield loss can occur with reticles of any size, including currently-used reticles that are approximately six inches square. With reticles of potentially larger sizes or having a rectangular shape, as are being considered for future use in the microelectronics industry, these effects of stress, bending, creep, and yield, etc., become even more important to control or prevent.

According to example inner reticle pods, one or more reticle supports of the base, one or more reticle contact surfaces of the cover, or a combination of these, can contact a reticle at locations of the reticle that are effective to control, balance, limit, or minimizes the magnitude of stress or deformation experienced by the reticle due to gravity or due to contact by a reticle contact surface. As described, one or more reticle supports can be positioned at one or more side positions of a reticle when the reticle is supported by the reticle supports; To achieve this, the one or more reticle supports may be located at one or more side positions of the base. Additionally, or alternately, one or more reticle contact surfaces may contact a reticle at one or more side positions of the reticle. The one or more reticle contact surfaces can be positioned at one or more side positions of the cover.

According to useful or preferred methods and reticle pods as described, reticle supports may engage a reticle at side locations of the reticle that are equally spaced from one another (adjacent reticle supports are equally spaced) and from each end of the reticle. Reticle supports (or reticle contact surfaces) are said to be “equidistant” along a length of a reticle if distances between adjacent reticle supports (or adjacent reticle contact surfaces), and distances between each end of a reticle and a nearest reticle support (or reticle contact surface) are approximately equal. Distances being “approximately equal” as used herein means that distances are within 10 or 5 percent of a referenced distance.

Also according to example inner reticle pods, the total number of contact points between a reticle and the inner reticle pod interior (i.e., locations of contact between the reticle and reticle supports of the base and reticle contact surfaces of the cover) can be minimized, i.e., fewer such contact points can be used where possible to reduce stress or deformation of a reticle. Generally, the number and locations of reticle supports and the number and locations of reticle contact surfaces can be designed to keep the reticle as flat as possible while the reticle is supported at the inner reticle pod interior, to thereby reduce or minimize the amount (magnitude) of stress or deformation experienced by the reticle.

The described features of an inner reticle pod base and attendant reticle supports, and an inner reticle pod cover and attendant reticle contact surfaces, can be adapted for use with any design of an inner reticle pod, including inner reticle pod designs that are known and currently used in the semiconductor processing industry, in combination with equipment used for performing EUV photolithography. Examples of useful inner reticle pods include those of a type known as an inner reticle pod (or “cassette”) of a dual containment pod that contains the inner reticle pod within a second or outer pod (a.k.a., “shell”), e.g., a dual containment pod sometimes referred to as a reticle “SMEF” pod. Examples of inner reticle pod designs are described in US patent publications 2023/0129336 and 2021/0057248.

In more detail, an inner reticle pod can include a lower portion or “base” that serves as a lower or bottom structure of the inner reticle pod, and an upper portion or “cover” that serves to cover the base and a reticle that is supported by the base. The base and the cover, when assembled with the cover placed over the base, define an inner reticle pod interior that is adapted to contain, enclose, and protect a reticle supported by the base.

Each of the base and the cover is generally shaped to have a length and a width in horizontal directions, with two parallel sides along the length and two parallel ends along the width. The sides are connected to the ends at corners to form right angles between the sides and the ends. The first side has a length, the second side has a length, and the lengths of the two sides are equal. The first end has a length, the second end has a length, and the lengths of the two ends are equal. The length of the two sides may be the same as the length of the two ends and the inner reticle pod has a square shape. Alternatively, the length of the two sides may be greater than the length of the two ends and the inner reticle pod has a rectangular shape.

Each of the base and the cover includes a perimeter that is defined by the two sides and the two ends of the base and the cover. When the base and the cover are assembled to contain an enclosed reticle, surfaces of the sides and ends of the base contact surfaces of the sides and ends of the cover, and the base and the cover define an inner reticle pod interior that contains the reticle.

An example base is substantially planar and has an upper base surface extending horizontally between the base sides and the base ends. The base includes reticle supports that are located on the upper base surface at locations to support a reticle while reducing an amount of stress or deformation of the reticle, i.e., the locations of the reticle supports attempt to distribute stress (minimize the difference in stress levels) over the length, width, and area of the reticle, and minimize deformation (e.g., sagging due to gravity) of the reticle. Examples of inner reticle pod bases that can be adapted to designs of the present description are described in U.S. Pat. Nos. issued patents 9,745,119 and 9,919,863, and United States patent publication 2021/0057248, the entireties of which are incorporated herein by reference.

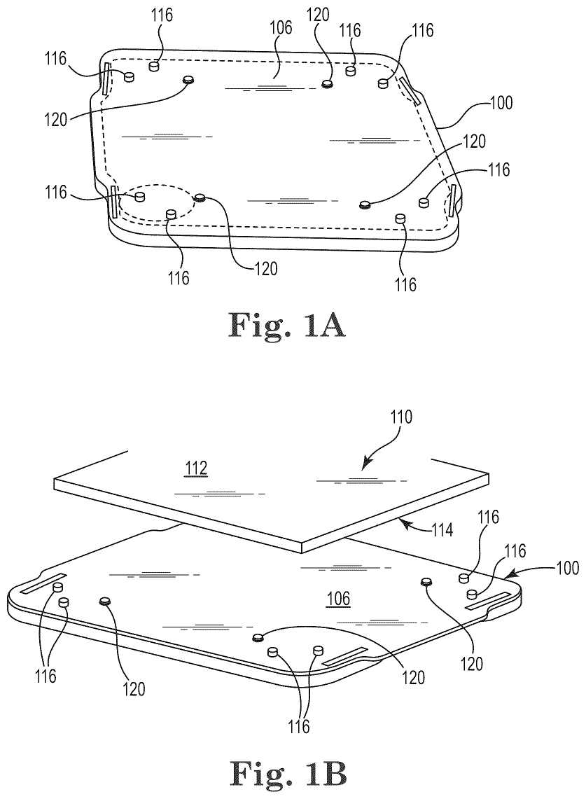

FIGS. 1A and 1B show an example of a base 100, components thereof, and reticle 110. Base 100 includes a location at a top surface 106 that approximates a size and shape of a reticle. Patterned surface 114 of reticle 110 may be disposed in a “downward” direction toward upper surface 106 of base 100. Multiple retainer pins 116 are fixedly attached to upper surface 106 of base 100 at locations near a perimeter of a space for locating reticle 110 above surface 106 and are effective to guide the placement of reticle 110 to a desired location above surface 106.

Example base 100 includes a plurality of openings that extend vertically through the base, with reticle supports 120 being located within those openings. Each reticle support 120 is located within an opening and includes an upper surface that is located a small height above upper surface 106 of base 100 to allow the upper surfaces of reticle supports 120 to contact a bottom (patterned) surface 114 of reticle 110 and to position the bottom surface 114 a slight distance above surface 106, creating a gap extending horizontally between reticle 110 and surface 106. The gap may be of any useful size, for example in a range of from 0.001 to 0.010 inches. Base 100 includes multiple reticle supports 120, one or more of which may be located at a side position of base 100 to provide balanced support for reticle 110 with reduced stress or deformation of the reticle.

An example cover includes an approximately planer horizontal top portion and four vertically-extending walls that extend vertically downward from the top portion along the two sides and the two ends to bottom surfaces of the walls that form a perimeter of the cover that is adapted to contact a perimeter of the base. Example covers include one or more reticle retainers located and held at an aperture that passes through the planar horizontal top portion of the cover between an interior and an exterior of the cover.

Example reticle retainers can include an inner reticle segment that includes one or more reticle contact surfaces located within an interior of the cover at a position to contact a reticle held at the interior. The inner reticle segment is connected to an outer contact surface located at an exterior of the cover. During use to maintain a position of the reticle within the reticle pod interior, pressure applied to the outer contact surface causes the one or more inner reticle contact surfaces at the cover interior to move in a direction toward a reticle held at the inner reticle pod interior and supported by the base. The pressure causes the inner reticle segment to move toward an edge or upper surface of the reticle, which causes the one or more reticle contact surfaces to contact the reticle and limit movement of the reticle within the inner reticle pod interior. A cover or “dome” of an outer reticle pod includes at least one contact pad that is located within the dome and adapted to contact and apply pressure to an outer contact surface of the reticle retainer to actuate the inner reticle segment, causing the one or more reticle contact surfaces to move toward and engage the reticle.

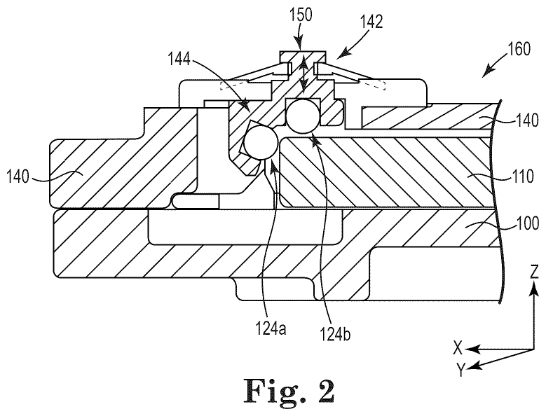

A specific example of an inner reticle pod cover is shown at FIG. 2. FIG. 2 is a cross-sectional view of an assembled inner reticle pod 160 having base 100, cover 140 that includes reticle retainer 142, and reticle 110 supported by reticle supports (not shown) of base 100. Reticle retainer 142 includes a body that includes inner reticle segment 144 with reticle contact surfaces 124a and 124b, and outer contact surface 150. The body extends through an opening provided in cover 140 to position inner reticle segment 144 within an interior of cover 140, while outer contact surface 150 is accessible from an exterior of cover 140. The body can be connected to a resilient member that includes outer contact surface 150, which is accessible at the exterior of cover 140. The resilient member can be an elastomeric disk that is configured to bias reticle contact surfaces 124a and 124b in a retracted position. In the retracted position, reticle contact surfaces 124a and 124b are positioned away from reticle 110 in the absence of a downward force applied to outer contact surface 150 in the z-direction. When force is applied to outer contact surface 150, reticle contact surfaces 124a and 124b move to engage reticle 110 to limit movement of reticle 110. Example cover 140 includes multiple reticle contact surfaces, one or more of which may be located at side positions of cover 140 to balance or reduce the amount of stress and deformation of reticle 100 caused by contact with the reticle contact surfaces.

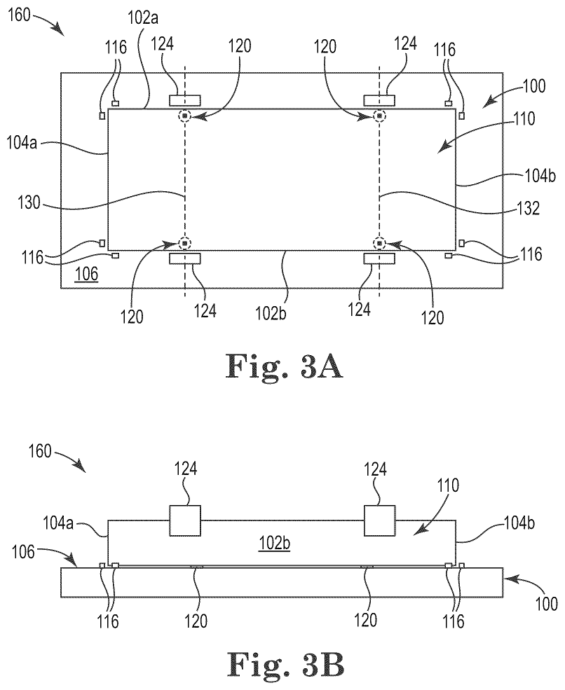

FIGS. 3A, 3B, 4A, 4B, and 5 show example components of assembled inner reticle pods 160 having a base, a cover (not shown) that includes multiple reticle contact surfaces, and a reticle supported by reticle supports of the base. Example bases include one or more reticle supports located at a side position of the base that is a relatively shorter distance from a base side (measured perpendicularly from a base side closest to the reticle support) compared to a relatively greater distance from a base end (measured perpendicularly from a base end closest to the reticle support). This position of a reticle support of a base can be referred to as a “side position” of the base.

Example covers may include one or more reticle contact surfaces located at a relatively shorter distance from a cover side (measured perpendicularly from a cover side closest to the reticle contact surface) compared to a relatively greater distance from a cover end (measured perpendicularly from a cover end closest to the reticle contact surface). This position of a reticle contact surface of a cover can be referred to as a “side position” of the cover.

A cover may optionally include one or more reticle contact surfaces that align with a reticle support of a base, meaning that a reticle contact surface is positioned at approximately the same location as a reticle support along a side of a reticle, e.g., at a location that is at approximately the same lengthwise position along a reticle side (within 5 or 10 percent) as the reticle support.

FIGS. 3A and 3B show assembled inner reticle pod 160 having base 100 supporting reticle 110, retainer pins 116, reticle supports 120, and reticle contact surfaces 124 of a cover (not shown). Reticle 110 has reticle sides 102a and 102b and reticle ends 104a and 104b, which correspond to sides and ends of base 110 and the cover (not shown) of comparable shape and larger (e.g., proportionally larger) dimensions. Each reticle support 120 and reticle contact surface 124 is located at a side position of reticle 110, meaning a location of the reticle that is closer to a reticle side 102a or 102b than to a reticle end 104a or 104b; reticle supports 120 are also located at side positions of base 110 (i.e., closer to a side of base 110 than to an end of base 110), and reticle contact surfaces 124 are located at side positions of the cover (not shown).

Still referring to FIGS. 3A and 3B, in a preferred example, each reticle support 120 and reticle contact surface 124 can be located at a position along a length of a reticle side 102a or 102b that is a distance that is approximately equal to (e.g., within five or ten percent based on total length of the reticle side) one-third of the length of a reticle side 102a or 102b from a reticle end 104a or 104b. According to this spacing, reticle support 120 and reticle contact surfaces 124 are considered to be “equidistant” between the two reticle ends along the lengths of the reticle sides. Two reticle supports 120 and two reticle contact surfaces 124 are located at a location of line 130, which is located a distance of about one-third of the total length of a reticle side 102a, 102b from reticle end 104a and two-thirds of the total length of a reticle side 102a, 102b from reticle end 104b; two reticle supports 120 and two reticle contact surfaces 124 are located at a location of line 132, which is located a distance of about two-thirds of the total length of a reticle side 102a, 102b from reticle end 104a and one-third of the total length of a reticle side 102a, 102b from reticle end 104b.

In alternate examples, reticle supports 120 and reticle contact surfaces 124 may be positioned differently, i.e., not in equidistant arrangement between the reticle ends. For example, two reticle supports 120 and two reticle contact surfaces 124 may be located on line 130, located a distance of about one-fourth of the total length of a reticle side 102a, 102b from reticle end 104a and three-fourths of the total length of a reticle side 102a, 102b from reticle end 104b; two reticle supports 120 and two reticle contact surfaces 124 may be located at a location of line 132, which may be located a distance of about one-fourth of the total length of a reticle side 102a, 102b from reticle end 104a and three-fourths of the total length of a reticle side 102a, 102b from reticle end 104b.

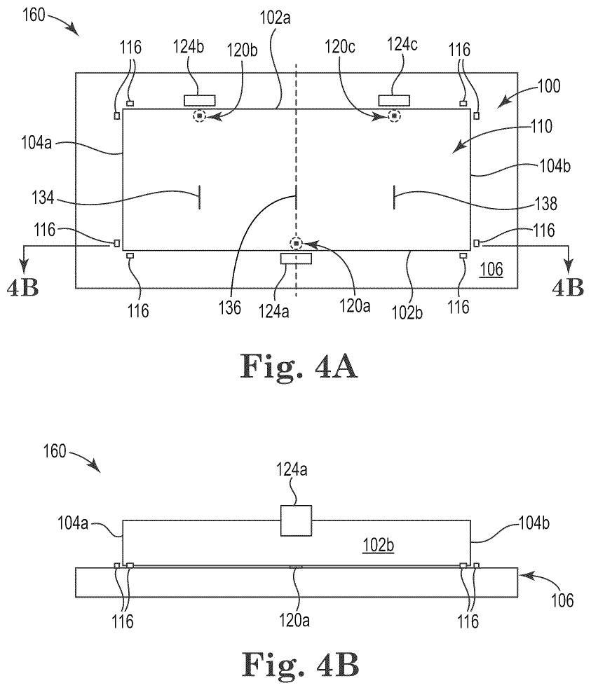

FIGS. 4A and 4B show another example of an assembled inner reticle pod 160 having base 100 supporting reticle 110, retainer pins 116, reticle supports 120a, 102b, and 120c, and reticle contact surfaces 124a, 124b, and 124c of a cover (not shown). Reticle support 120a, 120b, and 120c, and reticle contact surface 124a, 124b, and 124c are located at side positions of reticle 110, closer to a reticle side 102a or 102b than to a reticle end 104a or 104b. According to this example, reticle support 120a and reticle contact surface 124a are located at a “medial side position” of reticle side 102b, approximately (e.g., within 10 percent of a total length of reticle side 104a) at a midline 136 along the length of reticle 110. Reticle supports 120b and 120c, and reticle contact surfaces 124b and 124c, are located at non-medial side positions of reticle side 102a, which may be approximately at locations equal to one-third and two-thirds of the length of reticle side 102a, or approximately at locations equal to one-fourth and three-fourths of the length of reticle side 102a, or at other locations.

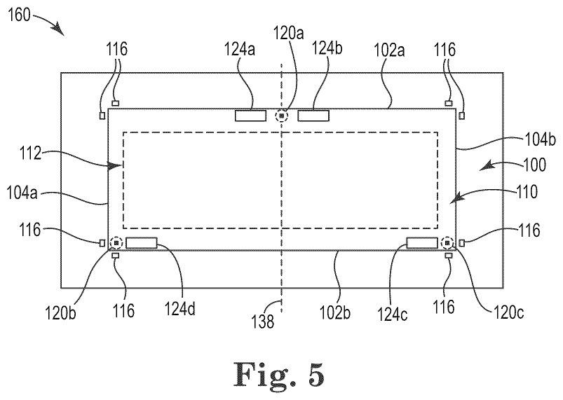

FIG. 5 shows another example of an assembled inner reticle pod 160 having base 100 supporting reticle 110, retainer pins 116, reticle supports 120a, 120b, and 120c, and reticle contact surfaces 124a, 124b, 124c, and 124d of a cover (not shown). Reticle support 120a and reticle contact surfaces 124a and 124b are located at side positions of reticle 110 that are closer to reticle side 102a than to a reticle end 104a or 104b. According to this example, reticle support 120a is located at a “medial side position” that is approximately (e.g., within 10 percent of a total length of reticle side 104a) at a midline 138 along the length of side 102a of reticle 110. Reticle contact surfaces 124a and 124b are located near reticle support 120a, e.g., within 10 percent of a total length of reticle side 102a from reticle support 120a. Reticle supports 120b and 120c and reticle contact surfaces 124c and 124d are located near reticle side 102b and may be at a side position of reticle 110, closer to reticle side 102b than to a reticle end 104a or 104b, e.g., may be at a non-medial side position of reticle 110, or may be at a corner position that is equidistant from reticle side 102b and a reticle end 104a or 104b.

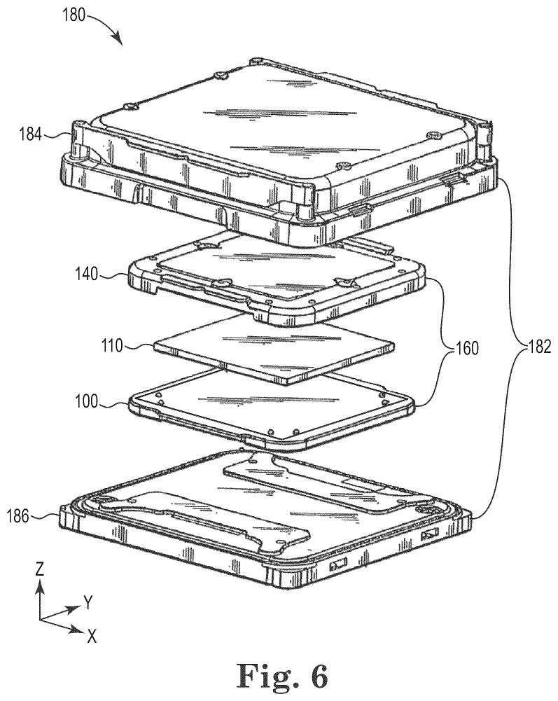

FIG. 6, shows an example of a dual containment pod that incudes an outer pod and an inner reticle pod as described. FIG. 6 is a perspective, exploded view of example reticle pod 180. Reticle pod 180 includes an inner reticle pod 160 and an outer pod 182. For example, reticle pod 180 can be, but is not limited to, a reticle pod for EUV processing of photolithography masks, or the like. Inner reticle pod 160 may be square as illustrated, or may be rectangular, e.g., having a length or width of at least 6 or 8 inches.

Inner reticle pod 160 includes cover 140 and base 100 as described. As illustrated, cover 140 and base 100 are configured to be engaged together at opposing perimeters to provide contact and sealing between base 100 and cover 140. When so engaged, cover 140 and base 100 define an inner reticle pod interior that is sized and shaped to contain reticle 110. At least one of cover 140 and base 100 can include one or more reticle contact surfaces and reticle supports, respectively, as described herein.

Outer pod 182 includes outer pod dome 184 and outer pod door 186. Outer pod 182 is configured to accommodate inner reticle pod 160 within an internal space defined by outer pod dome 184 and outer pod door 186. The outer pod dome 184 can be secured to outer pod door 186 to enclose the internal space and contain inner reticle pod 160, for example during transport and handling of reticle pod 180. Outer pod dome 184 and outer pod door 186 can each include or be made entirely of one or more polymer materials or any other suitable materials.

At FIGS. 3A, 3B, 4A, 4B, and 5, base 100, reticle 110, and cover 140 are illustrated as being rectangular in shape. Reticle 110, for example, may have width dimension of at least 6 inches and a length dimension that is greater than the width dimension, e.g., at least 8, 10, or 12 inches. Alternately, base 100, reticle 110, and a cover of an inner reticle pod, as well as an outer pod that contains an inner reticle pod, may also be square, e.g., reticle 110 may have a length dimension that is approximately equal to a width dimension, e.g., each being at least 6 or at least 8 inches.

A reticle or inner reticle pod that has a square shape has a length along each side of the square-shaped reticle. A typical length of currently-commercial reticles is 6 inches by six inches. Larger reticles having at least one of a length or width dimension that is greater than 6 inches, e.g., at least 8, 9, 10, or 12 inches, are contemplated to improve efficiency of photolithographic processing. Accordingly, reticle pods as described can have a square or a rectangular dimension to accommodate a reticle having at least one of a length or width dimension that is greater than 6, 8, 9, 10, or 12 inches.

Aspect 1. An inner reticle pod adapted to contain a reticle, the inner reticle pod comprising a base and a cover,

the base comprising:
an upper base surface, a first base side, a second base side, a first base end extending between the first base side and the second base side, and a second base end extending between the first base side and the second base side,
at least three reticle supports on the upper base surface, at least one of the at least three reticle supports being positioned at a side position of the base that is nearer to a base side than to a base end,

the cover adapted to engage the base and contain a reticle supported by the reticle supports.

Aspect 2. The inner reticle pod of Aspect 1, the first base side and the second base side having a base length, the first base end and the second base end having a base width, the base length being greater than the base width.

Aspect 3. The inner reticle pod of Aspect 2, the cover having a first cover side, a second cover side, a first cover end extending between the first cover side and the second cover side, and a second cover end extending between the first cover side and the second cover side, the first cover side and the second cover side having a cover length, the first cover end and the second cover end having a cover width, the cover length being greater than the cover width.

Aspect 4. The inner reticle pod of Aspect 1, the cover comprising at least three reticle contact surfaces adapted to limit movement of a reticle supported by the at least three reticle supports, while the cover engages the base with a reticle supported by the reticle supports.

Aspect 5. The inner reticle pod of Aspect 4, wherein with the cover placed over the door, at least one of the at least three reticle contact surfaces is aligned with a reticle support.

Aspect 6. The inner reticle pod of Aspect 1, the base comprising:

a first reticle support positioned at a medial side position of the first base side,

a second reticle support positioned at a non-medial side position of the second base side, and

a third reticle support positioned at a non-medial side position of the second base side.

Aspect 7. The inner reticle pod of Aspect 6, wherein with a reticle supported by the at least three reticle supports, the second reticle support and the third reticle support are located at equidistant locations between the first reticle end and the second reticle end.

Aspect 8. The inner reticle pod of Aspects 6 or 7, the cover having a first cover side, a second cover side, a first cover end extending between the first cover side and the second cover side, and a second cover end extending between the first cover side and the second cover side, the cover comprising:

Aspect 9. The inner reticle pod of Aspect 1, the base comprising:

a first reticle support positioned at a non-medial side position of the first base side,

a second reticle support positioned at a non-medial side position of the first base side,

a third reticle support positioned at a non-medial side position of the second base side, and

a fourth reticle support positioned at a non-medial side position of the second base side.

Aspect 10. The inner reticle pod of Aspect 9, wherein with a reticle supported by the at least three reticle supports, the first and second reticle supports are located at equidistant locations between the first reticle end and the second reticle end, and the third and fourth reticle supports are located at equidistant locations between the first reticle end and the second reticle end.

Aspect 11. The inner reticle pod of Aspect 10, the cover having a first cover side, a second cover side, a first cover end extending between the first cover side and the second cover side, and a second cover end extending between the first cover side and the second cover side, the cover comprising:

a first reticle contact surface positioned at a non-medial side position of the first cover side,

a second reticle contact surface positioned at a non-medial side position of the first cover side,

a third reticle contact surface positioned at a non-medial side position of the second cover side, and

a fourth reticle contact surface positioned at a non-medial side position of the second cover side.

Aspect 12. The inner reticle pod of Aspect 11, wherein with the cover placed over the door, one or more reticle contact surfaces are aligned with one or more reticle supports.

Aspect 13. The inner reticle pod of Aspect 6, the cover having a first cover side, a second cover side, a first cover end extending between the first cover side and the second cover side, and a second cover end extending between the first cover side and the second cover side, the cover comprising:

a first reticle contact surface positioned at a medial side position of the first cover side, and

a second reticle contact surface positioned at a medial side position of the first cover side.

Aspect 14. The inner reticle pod of Aspect 13, the cover comprising:

a third reticle contact surface positioned along the second cover side, and

a fourth reticle contact surface positioned along the second cover side.

Aspect 15. The inner reticle pod of Aspect 1, the base comprising:

at least three apertures positioned vertically through the base,

a reticle support positioned within each of the at least three apertures, the reticle support comprising:
a reticle support body within the aperture,
an upper reticle support surface positioned above the upper base surface and adapted to support a reticle above the upper base surface.

Aspect 16. The inner reticle pod of Aspect 1, the base comprising a plurality of retainer pins adapted to maintain a position of a reticle supported by the reticle supports.

Aspect 17. The inner reticle pod of Aspect 1, adapted to support a reticle comprising a plate having a patterned surface, on the reticle support surfaces.

Aspect 18. The inner reticle pod of Aspect 1, comprising a reticle supported by the reticle supports.

Aspect 19. A method of containing a reticle in an inner reticle pod comprising a base and a cover, the method comprising:

on a base comprising:
an upper base surface, a first base side, a second base side, a first base end extending between the first base side and the second base side, and a second base end extending between the first base side and the second base side,
at least three reticle supports on the upper base surface,

placing a reticle on the base with the reticle supported by the at least three reticle supports, the reticle comprising a first reticle side, a second reticle side, a first reticle end extending between the first reticle side and the second reticle side, and a second reticle end extending between the first reticle side and the second reticle side, at least one of the at least three reticle supports being positioned at a side position of the reticle that is nearer to a reticle side than to a reticle end, and

placing a cover over the base to contain the reticle supported by the reticle supports.

Aspect 20. The method of Aspect 19, the first reticle side and the second reticle side having a reticle length, the first reticle end and the second cover end having a reticle width, the reticle length being greater than the reticle width.

Aspect 21. The method of Aspect 19, the cover comprising at least three reticle contact surfaces adapted to limit movement of the reticle supported by the at least three reticle supports, at least one of the at least three reticle contact surfaces being positioned at a side position of the reticle that is nearer to a reticle side than to a reticle end.

Aspect 22. The method of Aspect 19, the base comprising:

a first reticle support positioned at a medial side position of the first reticle side,

a second reticle support positioned at a non-medial side position of the second reticle side, and

a third reticle support positioned at a non-medial side position of the second reticle side,

when the reticle is supported by the at least three reticle supports.

Aspect 23. The method of Aspect 22, wherein the second reticle support and the third reticle support are located at equidistant locations along the second reticle side between the first reticle end and the second reticle end.

Aspect 24. The method of Aspect 19, the base comprising:

a first reticle support positioned at a non-medial side position of the first reticle side,

a second reticle support positioned at a non-medial side position of the first reticle side,

a third reticle support positioned at a non-medial side position of the second reticle side, and

a fourth reticle support positioned at a non-medial side position of the second reticle side,

when the reticle is supported by the reticle supports.

Aspect 25. The method of Aspect 24, the cover comprising:

a first reticle contact surface positioned at a non-medial side position of the first reticle side,

a second reticle contact surface positioned at a non-medial side position of the first reticle side,

a third reticle contact surface positioned at a non-medial side position of the second reticle side, and

a fourth reticle contact surface positioned at a non-medial side position of the second reticle side.

Aspect 26. The method Aspect 19, the base comprising:

a first reticle support positioned at a medial side position of the first reticle side,

a second reticle support positioned along the second reticle side, and

a third reticle support positioned along the second reticle side.

Aspect 27. The method of Aspect 19, the cover comprising:

a first reticle contact surface positioned at a medial side position of the first reticle side, and

a second reticle contact surface positioned at a medial side position of the first reticle side.

Aspect 28. The method of Aspect 27, the cover comprising:

a third reticle contact surface positioned along the second reticle side, and

a fourth reticle contact surface positioned along the second reticle side.

What is claimed is:

1. An inner reticle pod adapted to contain a reticle, the inner reticle pod comprising a base and a cover,
the base comprising:
an upper base surface, a first base side, a second base side, a first base end extending between the first base side and the second base side, and a second base end extending between the first base side and the second base side,
at least three reticle supports on the upper base surface, at least one of the at least three reticle supports being positioned at a side position of the base that is nearer to a base side than to a base end,
the cover adapted to engage the base and contain a reticle supported by the reticle supports.

2. The inner reticle pod of claim 1, the first base side and the second base side having a base length, the first base end and the second base end having a base width, the base length being greater than the base width.

3. The inner reticle pod of claim 2, the cover having a first cover side, a second cover side, a first cover end extending between the first cover side and the second cover side, and a second cover end extending between the first cover side and the second cover side, the first cover side and the second cover side having a cover length, the first cover end and the second cover end having a cover width, the cover length being greater than the cover width.

4. The inner reticle pod of claim 1, the cover comprising at least three reticle contact surfaces adapted to limit movement of a reticle supported by the at least three reticle supports, while the cover engages the base with a reticle supported by the reticle supports.

5. The inner reticle pod of claim 4, wherein with the cover placed over the door, at least one of the at least three reticle contact surfaces is aligned with a reticle support.

6. The inner reticle pod of claim 1, the base comprising:
a first reticle support positioned at a medial side position of the first base side,
a second reticle support positioned at a non-medial side position of the second base side, and
a third reticle support positioned at a non-medial side position of the second base side.

7. The inner reticle pod of claim 6, wherein with a reticle supported by the at least three reticle supports, the second reticle support and the third reticle support are located at equidistant locations between the first reticle end and the second reticle end.

8. The inner reticle pod of claim 6, the cover having a first cover side, a second cover side, a first cover end extending between the first cover side and the second cover side, and a second cover end extending between the first cover side and the second cover side, the cover comprising:
a first reticle contact surface positioned at a medial side position of the first cover side,
a second reticle contact surface positioned at a non-medial side position of the first cover side, and
a third reticle contact surface positioned at a non-medial side position of the second cover side.

9. The inner reticle pod of claim 1, the base comprising:
a first reticle support positioned at a non-medial side position of the first base side,
a second reticle support positioned at a non-medial side position of the first base side,
a third reticle support positioned at a non-medial side position of the second base side, and
a fourth reticle support positioned at a non-medial side position of the second base side.

10. The inner reticle pod of claim 9, wherein with a reticle supported by the at least three reticle supports, the first and second reticle supports are located at equidistant locations between the first reticle end and the second reticle end, and the third and fourth reticle supports are located at equidistant locations between the first reticle end and the second reticle end.

11. The inner reticle pod of claim 10, the cover having a first cover side, a second cover side, a first cover end extending between the first cover side and the second cover side, and a second cover end extending between the first cover side and the second cover side, the cover comprising:
a first reticle contact surface positioned at a non-medial side position of the first cover side,
a second reticle contact surface positioned at a non-medial side position of the first cover side,
a third reticle contact surface positioned at a non-medial side position of the second cover side, and
a fourth reticle contact surface positioned at a non-medial side position of the second cover side.

12. The inner reticle pod of claim 11, wherein with the cover placed over the door, one or more reticle contact surfaces are aligned with one or more reticle supports.

13. The inner reticle pod of claim 6, the cover having a first cover side, a second cover side, a first cover end extending between the first cover side and the second cover side, and a second cover end extending between the first cover side and the second cover side, the cover comprising:
a first reticle contact surface positioned at a medial side position of the first cover side, and
a second reticle contact surface positioned at a medial side position of the first cover side.

14. The inner reticle pod of claim 13, the cover comprising:
a third reticle contact surface positioned along the second cover side, and
a fourth reticle contact surface positioned along the second cover side.

15. The inner reticle pod of claim 1, the base comprising:
at least three apertures positioned vertically through the base,
a reticle support positioned within each of the at least three apertures, the reticle support comprising:
a reticle support body within the aperture,
an upper reticle support surface positioned above the upper base surface and adapted to support a reticle above the upper base surface.

16. The inner reticle pod of claim 1, the base comprising a plurality of retainer pins adapted to maintain a position of a reticle supported by the reticle supports.

17. The inner reticle pod of claim 1, adapted to support a reticle comprising a plate having a patterned surface, on the reticle support surfaces.

18. The inner reticle pod of claim 1, comprising a reticle supported by the reticle supports.
